(19) United States
(12) Patent Application Publication
(10) Pub. No.: US 2012/0018821 A1
(43) Pub. Date: Jan. 26, 2012

(54) MICRO FORCE SENSOR PACKAGE FOR SUB-MILLINEWTON ELECTROMECHANICAL MEASUREMENTS

(75) Inventor: Felix Beyeler, Regensdorf (CH)

(73) Assignee: FEMTO TOOLS GMBH, Zurich (CH)

(21) Appl. No.: 13/262,295

(22) PCT Filed: Jan. 4, 2010
(86) PCT No.: PCT/EP2010/050014

§ 371 Date: Sep. 30, 2011

(30) Foreign Application Priority Data
Mar. 31, 2009 (EP) 09156798.2

(51) Int. Cl. H01L 29/84

(52) U.S. Cl. 257/418; 257/417; 257/E29.324

(57) ABSTRACT

A force sensor package includes the following main parts: a MEMS force sensor, an interface circuit converting a change of capacitance into an analog or digital sensor output signal, and a substrate on which the MEMS force sensor and the IC are attached. The interface circuit is a die in order to minimize the size of the force sensor. The MEMS force sensor and the interface circuit are attached to the substrate by an adhesive, e.g. glue. Electrical contacts are then realized by wire-bonding. Alternatively, the two parts may also be attached to the substrate by a flip-chip process using solder. A protective cover may be placed over the assembly.

The invention relates to a force sensor package according to claim 1.

Multiple methods for measuring force from the nano-newton (10⁻⁹N) to millinewton (10⁻³N) range exist such as atomic force microscopes, microscales, piezoresistive cantilevers and capacitive force sensors. These sensors have been applied in the research fields of biomaterials characterization and biological research, see [1]-[5]. Capacitance is a measure of the electrical charge between two conductors separated by an air gap. A load applied to the sensor causes a deflection. As the conductors are moved closer to or farther from one another, the air gap changes, and so does the capacitance. The principle of capacitive micro force sensing is simple and effective and features an excellent sensitivity. Due to the single-crystalline silicon structure of the sensor the results are highly repeatable and the sensors are less likely to degrade over time.

Few work is published about the packaging and inter-facing of capacitive micro force sensors as well as electro-static microgrippers. A sensor package for a piezoresistive membrane force sensor is presented in [6]. Due to the fragility of these devices packaging is a great challenge. The package provides the interface between the components and the overall system. The package of a MEMS force sensor or gripper serves two main functions:

i) mechanical support and protection from environment

ii) electrical connection to the readout electronics

Due to the nature of Micro-Electro-Mechanical System

MEMS being mechanical, the requirement to support and protect the device from mechanical shock, contamination by particles and other physical damage is an important issue. Unlike inertial sensors such as accelerometers or gyroscopes, a micro force sensor cannot be fully encapsulated, since the load has to be applied to the sensor probe. The same problem also applies to microgrippers, which require the gripper arms to interact with the environment outside the package. Traditional hermetic packages cannot be used in that case. Therefore, the force sensors and grippers are directly mounted to a printed circuit board PCB or a hybrid-like ceramic substrate and have a housing to protect it from mechanical damage.

In WO 2007/147239 A[1] and WO 2005/121812 A1 [2] a capacitive micro force sensor design is presented. However, the design of the sensor package is not described in [1] and [2]. In US 2007/0251328 A1 [6] the surface mount package of a piezoresistive micro sensor is described which measures the force as a change of electrical resistance. The sensor in this work measures the force as a change of capacitance. Unlike the sensor in this work the microfabricated sensor element in US 2007/0251328 A1 [6] is not overhanging the substrate. Also, the sensor element in US 2007/0251328 A1 [6] is coupled to an actuator which is not the case in this work. In US 2007/0251328 A1 [6] the force transmission is only perpendicular to the substrate. The design in US 2007/0251328 A1 [6] does not feature a detachable protective cover and does not feature the ability to make electromechanical measurements.

The goal of the present invention is to provide a miniature capacitive micro force sensor package suitable for the integration in systems where the space is limited. The package must include features for interfacing the microfabricated sensor element, reducing parasitic capacitance, programming the interface IC, conditioning the interface IC as well as shielding of the sensing element and the electronics. Additionally it is a task to provide a force sensor package also for an industrial automatic production and not only for a small number of samples. The force sensor should be suitable for simultaneously measuring both mechanical and electrical properties of a test sample. The setup should allow a placing of a protective housing in order to protect the sensitive microfabricated sensing element.

This goal is reached by a capacitive micro force sensor package specified with the features given in claim 1.

Compared to the micro force sensor package design presented in [3] and [4], the size of the package according to this invention is significantly smaller. This enables the usage of the sensor where space is limited, which is the case when probing samples underneath a microscope lens or inside a scanning electron microscope. The size reduction is realized by using an unpackaged interface IC connected by solder bumps or wire-bonding. A beveled substrate improves the accessibility of the sensor probe to the sample.

This smaller size enables also to cover the sensor with a protective housing.

The proposed design includes electrical contacts for programming the interface IC as well as well as other components for conditioning of the IC which results in a higher sensor performance. By reducing the sensor package size and integrating ground planes the parasitic capacitance is reduced which results in a better signal to noise ratio of the sensor output signal.

Due to the fact, that the MEMS sensor probe overlaps the substrate the force transmission the package according to the present invention can measure forces from any direction of an applied force.

Other capacitive micro force sensors in [1]-[6] do not feature a detachable protective housing which reduces contamination with dust and helps storing and transporting the sensor without the risk of damaging the fragile microfabricated sensor structure. In many cases microfabricated sensors are damaged before the actual measurement starts. The protective housing prevents damaging the sensor during the integration into the measurement system.

Powering the capacitive sensor interface electronics by a standard USB power supply increases the user-friendliness. Since a PC is used for data acquisition anyway, the usage of the USB power means that no additional power supply is required.

For probing very small objects as well as for the electro-mechanical probing of small samples a sharp tip is required which cannot be fabricated on wafer level. The usage of metal tips attached to the sensor overcomes this problem. The tip is electrically connected to the sensor probe and to the connector on the substrate. The micro force sensors presented in [1] to [6] do not feature the ability of electro-mechanical measurements.

The working principle of the invention will now be described more in detail with reference to the accompanying drawings wherein:

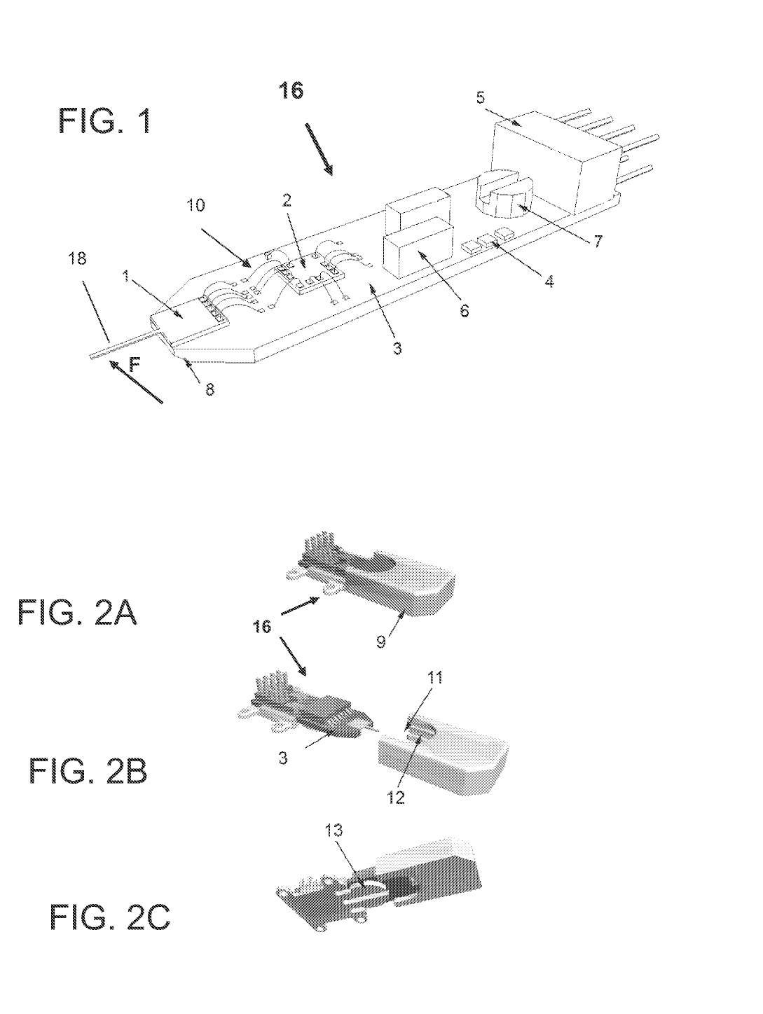

FIG. 1 describes the build-up of a capacitive micro force sensor package including the microfabricated sensing element, the interface IC which are mounted on the substrate without a protective cover.

FIG. 2a) shows a closed configuration for storage and transport of the force sensor package;

FIG. 2b) shows the same force sensor package with the detached protective cover;

FIG. 2c) shows the bottom of the force sensor package where a snap-mechanism for the attachment and detachment of the protective cover;

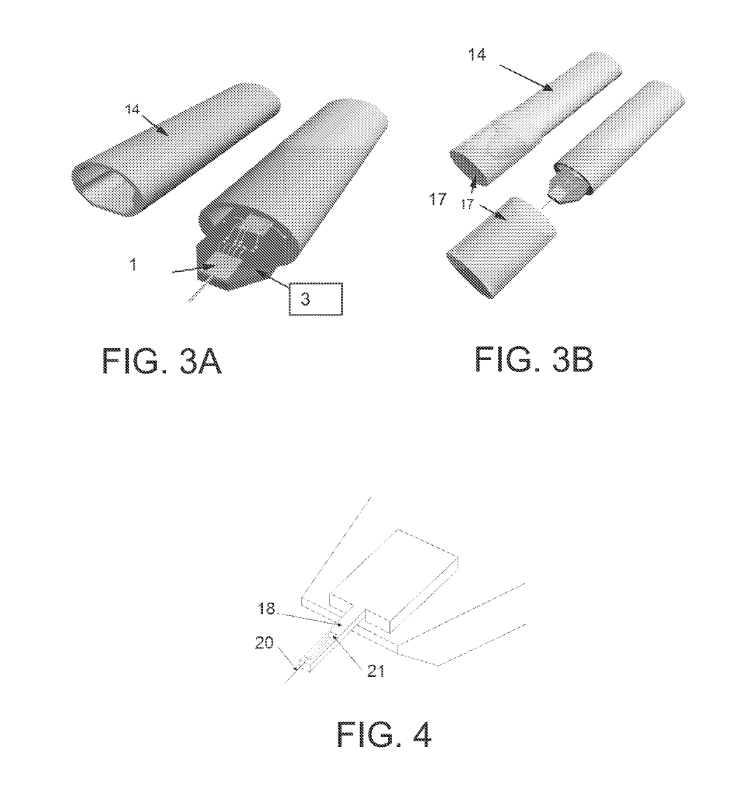

FIG. 3a) shows the force sensor package with a tube-shaped protective cover, a slide mechanism is used to slide the sensor out of the tube for operation and measurement;

FIG. 3b) shows a tube-shaped force sensor package with a additional detachable cover;

FIG. 4 shows the microfabricated sensing element with a sharp metal tip attached to the force sensor for electromechanical measurements and for probing very small sample areas.

The Basic Sensor Package Buildup comprises three main parts as shown in FIG. 1:

1. a MEMS force sensor 1; which can be a capacitive MEMS force sensing probe or a force sensing microgripper;

2. an interface circuit IC 2 which converts the change of capacitance into an analog or digital sensor output signal;

3. a substrate 3 on which the MEMS transducer 1 and the IC 2 are attached to. This substrate 3 may be a printed circuit board PCB which contains the pads for electrical contacting of the MEMS force sensor and the IC 2.

The MEMS capacitive force sensor 1 and the capacitive interface circuit chip 2—the latter not being embedded in a cover package—are directly attached to the substrate 3 by an adhesive (glue). The electrical contacts are then realized by wire-bonding 10. Alternatively, said two parts may also be attached to the substrate by a flip-chip process using solder.

The interface circuit chip 2 is located next—next in the meaning of very close—to the MEMS force sensor 1 to improve the sensor output signal performance. Unlike some conventional sensors no cables are used between the MEMS force sensor 1 and the interface circuit chip 2—in the following just called IC for simplicity—which adds parasitic capacitance. The short distance between the MEMS force sensor 1 and the IC 2 makes the force sensor package 16 less sensitive to electrical disturbances.

Keeping the sensor package 16 as small as possible is crucial for applications where the space is very limited. This is for example the case in vacuum chambers of scanning electron microscopes. By using a raw IC die 2 instead of a packaged I , the size of the sensor package 16 can be significantly reduced, since the footprint of the die 2 is usually much smaller.

The IC 2 may be programmable by an EPROM such that the sensitivity, range and the offset of the force sensor 1 can be programmed. Also, the EPROM may be used for saving sensor calibration data. Programmable ICs 2 usually require additional electrical wiring. These electrical connections are not used any more after the programming of the IC. To save space and costs, these electrical connections may be temporary realized by electrical probes. The pads for contacting the substrate 4 are usually much smaller than a regular connector. The IC 2 may also include a low-pass filter to reduce the noise level of the force sensor 1.

For connecting the sensor package 16 to the data acquisition system DAQ a connector 5 is used. The connector 5 is chosen such that the cable is parallel to the probe of the MEMS force sensor 1. In most cases this simplifies the measurement setup. The connector 5 is placed on the opposite side of the MEMS force sensor 1. This reduces the risk that the fragile MEMS force sensor 1 is damaged by the plug/unplug procedure by accidentally touching it.

For improving the force sensor 1 performance a high quality supply voltage is important. Unstable voltage supplies may result in a higher noise level or a higher sensor drift. Therefore, capacitors 6 may be included in the sensor package to stabilize the force sensor supply voltage. The capacitors are ideally placed close to the IC 2.

Optionally, the substrate 3 has one or more holes 7 for attaching the package to a positioning system by a screw. The hole 7 is located in a large distance from the MEMS force sensor 1. This reduces the risk of accidentally touching the fragile MEMS force sensor 1 and damaging it.

All components may be placed on the topside of the substrate 3 using surface mount connectors and capacitors. This simplifies the attachment of the force sensor package 16 to metal positioning systems without creating a short in the electronics of the sensor package.

Resistors for the conditioning of the interface IC 2 may be soldered to the substrate 3.

The MEMS force sensor 3 may be on a separate miniature substrate which is plugged on the other substrate by a connector. Broken sensor can then be replaced in a short time without having to replace the IC 2 and capacitors 6.

The substrate material may be ceramic to match the thermal expansion coefficient of the silicon MEMS force sensor 1.

The wire-bonded 10 interface IC 2 may be covered with glue to protect it against damage while the MEMS force sensor 1 is not covered.

The shape of the substrate is of great importance to make it suitable for a large part of force sensing applications. In many cases the size of the objects that should be characterized by the MEMS force sensor 1 or the force sensing microgrippers are micron sized objects also. By beveling the substrate in the front part 8 where the MEMS force sensor 1 is located, collisions between the substrate and the samples can be avoided. The accessibility of the sample area is increased. Also, the probing of the same micron sized sample using multiple force sensors is possible.

By choosing a thin substrate 3, smaller than 1.0 mm, the accessibility of samples lying on a flat sample holder as microscope glass slide or scanning electron sample holder is increased. In comparison, standard substrates normally feature a thickness of about 1.5 mm. By beveling the front part of the substrate underneath the MEMS force sensor 1 the minimum angle with which the sample can be investigated is minimized.

Electrical shielding is an important issue for capacitive micro force sensors 1. A ground plane may be used on the substrate 3 to form a partial “Faraday Cage” which protects the MEMS force sensor 1 and the IC 2 from electrical disturbances. Also, ground lines may be placed next to the MEMS force sensor 1. An electrode may be placed underneath the MEMS force sensor 1 to set the handle layer to ground potential or any other electrical potential to avoid <<floating>> potentials which may introduce errors into the measurement.

Choosing a suitable connector 5 for the miniature force sensor package is not trivial, since the package must stay as small as possible. Also, the connector 5 must be inexpensive, since the force package 16 is a disposable product. The following two connector types may be used as a inexpensive replacement for the connector in FIG. 1:

1. edge card connector: no connector on the substrate 3;

2. socket type connector: the sensor is plugged directly onto a small carrier board.

Instead of a connector flexPCBs or cables may be used to connect the sensor package 16 to the DAQ system. To make the sensor package less sensitive to electrical disturbances, coaxial connectors and cables or fully shielded miniature I/O connectors may be used, e.g. miniature USB connector.

MEMS force sensors 1 are easily damaged by mechanical overload when accidentally touching them or crashing them into another object. Many micro force sensors 1 are destroyed during shipping or during the integration into the measurements setup. Additionally, dirt and small particles may contaminate the microfabricated structures and damage the sensing element.

A protective housing 9 as shown in FIG. 2 is used to avoid damaging the MEMS force sensor. The protective housing protects the sensor during shipping and implementation.

The protective package 9 consists of two parts. One part is permanently attached to the substrate 3. The second is the protective cover 9 which is removed before the measurement but after mounting the sensor in the measurement setup. The protective cover 9 is held in place by a snap mechanism 13 as shown in FIG. 2. The snap mechanism 13 prevents the protective cover 9 from falling off. A guidance 12 ensures that the protective cover 9 cannot touch the fragile MEMS force sensor 1 during the detachment. A u-shaped cut-out 11 also reduces the risk that the protective cover 9 touches the MEMS force sensor 1 during the detachment.

An alternative housing method is using a circular or non-circular tube 14. The substrate 3 is inserted into this tube 14 which is open at one or both ends. Before the actual measurement the substrate 3 with the MEMS force sensor 1 is moved inside the tube 14 such that the MEMS force sensor 1 is sticking out at one end. The MEMS force sensor 1 is then ready for the experiment. The sensor cable is sticking out at the other end of the tube 14. This principle is illustrated in FIG. 3a).

Another method is additionally to use a detachable protective cover 17 in combination with the tube 14 as shown in FIG. 3b). In this case the substrate 3 would stay fixed inside the tube.

For storing and transporting the force sensor package in a clean environment, a air-tight plastic box may be used. MEMS force sensors 1 are packaged inside a cleanroom environment. The boxes guarantee that there is no contamination with particles during the storage and shipping after the force sensors are leaving the cleanroom. This also allows the easy storage and handling of force sensor packages 1 without the protective housing 14, 17 in a OEM version. The box may include a device for holding the sensor package 16, so it does not touch the box walls which may damage the MEMS force sensor 1.

For displaying, post-processing and visualization of the force sensor 1 reading, a data acquisition system DAQ is used. The DAQ system is connected to a computer by a standard USB interface. One or multiple micro force sensor packages 16 can be connected to the DAQ system by cables. Both the system DAQ and the micro force sensors package 1 are directly powered by the 5V USB power supply of the computer. No additional power supply is required. In case of a IC 2 with an analog output the DAQ system includes a A/D converter and USB driver electronics.

For applications in MEMS research, material research, nanotechnology and biology both mechanical and electrical properties of the sample may be important. The sensor probe of the MEMS force sensor 1 is electrically insulated from the capacitive sensing elements. The probe is electrically connected to the substrate 3 and the connector 5. This allows to use the probe for electrical measurements (voltage, current, electrical resistance) or to apply a voltage or a current to a sample. Both mechanical and electrical measurements can be performed simultaneously.

The material of the MEMS sensor probe is silicon. The contact resistance of silicon is high due to native oxide on the silicon surface. The probes may be coated with metal using physical vapor deposition, chemical vapor deposition or electroplating to reduce the contact resistance.

For probing very small samples (less than 50 μm) the MEMS sensor probe 18 dimensions may be too large. A sharp metal tip 20 can be attached to the MEMS sensor probe by glue or solder as shown in FIG. 4. For example, electro-chemically etched tungsten tips have a typical a tip radius in the range from 0.05 μm to 50 μm. Metal tips are electrically conductive and may therefore be used for electrical probing. Electrically conductive glue or solder is then used to fix the tips on the MEMS sensor probe. The sensor probe may be metalized 21 to reduce the electrical resistance between metal tip and MEMS sensor probe 18. Metal tips 20 may also be used to make the sensor probe longer which may be an advantage if the sample is immersed in liquid, where the MEMS force sensor 1 itself stays outside the liquid.

A self-alignment process may be used when assembling the metal tip 20 on the sensor probe 18. The surface tension forces of the solder or the glue align the tip and probe relative to each other.

### LIST OF USED REFERENCE NUMERALS AND ACRONYMS

1 MEMS capacitive force sensor

2 capacitive interface circuit chip, die, unpacked die, interface IC

3 substrate

4 contact pads

5 connector

6 capacitor or resistor for conditioning of the interface IC

7 hole

8 beveled front part

9 protective cover

10 wire bonding

11 u-shaped cut-out

12 guidance

13 snap mechanism

14 tube, circular or non-circular tube

16 force sensor package

17 detachable protective cover, second cover

18 MEMS sensor probe

20 metal tip

21 metalized sensor probe

A/D Analog/Digital

DAQ data acquisition system

F Force applied to the MEMS sensor probe

IC interface circuit IC

MEMS Micro-Electro-Mechanical System

OEM Original Equipment Manufacturer

PCB printed circuit board

USB Universal Serial Bus

### REFERENCES

[1] WO 2007/147239 A1 <<MEMS-BASED MICRO AND NANO GRIPPERS WITH TWO- AXIS FORCE SENSORS>> Applicant: SUN, Yu; KIM, Keekyoung

[2] WO 2005/121812 A1 <<MULTI-AXIS CAPACITIVE TRANSDUCER AND MANUFACTURING METHOD FOR PRODUCING IT>> Applicant: ETH ZURICH

[3] F. Beyeler, A. P. Neild, S. Oberti, D. J. Bell, Y. Sun, J. Dual, B. J. Nelson “Monolithically Fabricated Micro-Gripper with Integrated Force Sensor for Manipulating Micro-Objects and Biological Cells Aligned in an Ultrasonic Field” IEEE/ASME Journal of Microelectromechanical Systems, Vol. 16, No. 1, February 2007, pp. 7-15.

[4] F. Beyeler, S. Muntwyler, Z. Nagy, C. Graetzel, M. Moser, B. J. Nelson, “Design and calibration of a MEMS sensor for measuring force and torque acting on a magnetic microrobot” Journal of Micromechanics Microengineering, Vol. 18, 2008, pp 7.

[5] Y. Sun, B. J. Nelson, “MEMS Capacitive Force Sensors for Cellular and Flight Biomechanics”, Biomedical Materials, Vol. 2, No. 1, 2007, pp. 16-22.

[6] US 2007/0251328 A1 FORCE SENSOR PACKAGE AND METHOD OF FORMING THE SAME Applicants: Thirumani A. Selvan; Raghu Sanjee.

1-16. (canceled)

17. A force sensor package, comprising:
a substrate;
a MEMS capacitive force sensor mounted on said substrate and having a sensor probe on which a force is to be applied, said sensor probe overlapping said substrate for applying the force from any direction; and
a capacitive interface circuit chip connected with said MEMS capacitive force sensor for converting a capacitance signal of said MEMS capacitive force sensor into an output signal, said capacitive interface circuit chip being an unpackaged die mounted directly on said substrate.

18. The force sensor package according to claim 17, which further comprises a wire-bonded electrical connection between said MEMS force sensor and said interface circuit chip.

19. The force sensor package according to claim 17, which further comprises a flip-chip soldered electrical connection between said MEMS force sensor and said interface circuit chip.

20. The force sensor package according to claim 17, which further comprises at least one of at least one capacitor or at least one resistor disposed on said substrate for stabilizing a supply voltage for said interface circuit chip or for conditioning said interface circuit chip.

21. The force sensor package according to claim 17, which further comprises at least one connector soldered on said substrate.

22. The force sensor package according to claim 21, wherein said connector is an edge card connector or a socket type connector.

23. The force sensor package according to claim 17, which further comprises a ground plane integrated into said substrate for electrical shielding of said MEMS force sensor and said interface circuit chip.

24. The force sensor package according to claim 17, which further comprises a reversible mounting of said MEMS force sensor to said substrate for detaching and exchanging said MEMS force sensor if damaged.

25. The force sensor package according to claim 17, wherein said substrate has a beveled front part for improving accessibility of said MEMS force sensor.

26. The force sensor package according to claim 17, which further comprises a guide, and a protective housing placed over said substrate along said guide for preventing touching of said MEMS force sensor during detachment of said protective housing.

27. The force sensor package according to claim 26, which further comprises a snap mechanism fixing said protective cover for preventing said protective cover from falling off.

28. The force sensor package according to claim 17, wherein said MEMS sensor probe is selected from the group consisting of a capacitive force sensing probe, a capacitive force sensing cantilever and a force sensing microgripper.

29. The force sensor package according to claim 17, which further comprises a protective cover configured as a tube.

30. The force sensor package according to claim 29, which further comprises an additional detachable protective cover placed over said tube for protecting said sensor probe during transportation.

31. The force sensor package according to claim 17, wherein said sensor probe is electrically insulated from a remainder of said MEMS force sensor for electromechanical measurements.

32. The force sensor package according to claim 31, which further comprises a metal tip attached to said MEMS sensor probe with glue or solder.
